(19) United States
(12) Patent Application Publication
(10) Pub. No.: US 2019/0229299 A1
(43) Pub. Date: Jul. 25, 2019

(54) THIN-FILM PACKAGING METHOD FOR AN OLED DEVICE AND OLED DEVICE

(71) Applicant: Wuhan China Star Optoelecronics Semiconductor Display Technology Co., Ltd., Wuhan (CN)

(72) Inventors: Simin PENG, Wuhan (CN); Jiangjiang JIN, Wuhan (CN); Hsiang-lun HSU, Wuhan (CN)

(21) Appl. No.: 16/051,738

(22) Filed: Aug. 1, 2018

Related U.S. Application Data
(63) Continuation of application No. PCT/CN2018/083361, filed on Apr. 17, 2018.

(30) Foreign Application Priority Data
Jan. 24, 2018 (CN) 201810071720.5

(51) Int. Cl. H01L 51/56; H01L 51/00; H01L 51/52

(52) U.S. Cl. CPC H01L 51/56; H01L 51/0097; H01L 51/0018; H01L 51/5256; G03F 7/16; H01L 2251/303; H01L 2251/5338; H01L 2251/558; H01L 2251/301

(57) ABSTRACT

A thin-film packaging method for OLED device and an OLED device are disclosed. The method comprises: providing an OLED device to be packaged, and the OLED device to be packaged includes a light-emitting layer; through a lithography patterning technology to alternately form an inorganic thin film and an organic thin film on the OLED device in order to perform a thin-film packaging for the OLED device; wherein, the step of alternately forming an inorganic thin film and an organic thin film includes: forming a photoresist layer that surrounds the light-emitting layer of the OLED device on the OLED device to be packaged, and forming the inorganic thin film and the organic thin film on an opening region of the photoresist layer. The present invention can avoid a shadow effect of a mask, an overflow problem of ink at the edge, and can achieve a narrow frame requirement of the device.

### CROSS REFERENCE

This application is a continuing application of PCT Patent, Application No. PCT/CN2018/083361, filed on Apr. 17, 2018, entitled “thin-film packaging method for an OLED device and OLED device”, which claims priority to China Patent Application No. 201810071720.5 filed on Jan. 24, 2018, both of which are hereby incorporated in its entireties by reference.

### FIELD OF THE INVENTION

The present invention relates to a packaging technology field of OLED, and mora particularly to a thin-film packaging method for an OLED device and OLED device.

### BACKGROUND OF THE INVENTION

A flexible OLED display panel has features of low power consumption and bendable so as to bring a profound influence to an application of the wearable device. Using a plastic material to replace a glass material to manufacture a display screen such that the display screen is more durable and lighter. The flexible OLED display device adopts a thin film encapsulation (TFE). Through multiple layers of inorganic/organic, a steam invasion path is extended such that the device can stop the steam with a flexible function.

In the conventional art, one encapsulation art is: an organic monomer forms a polymer having a certain chain length after a chemical reaction under the function of Plasma. Then the polymer is deposited in a substrate, that is, an organic layer. However, in the deposition process, some of the organic layer is shifted out off an organic packing region in order to form a shadow effect. When the organic layer is shifted to a film coating region of an inorganic layer, an adhesion force among layers will decrease such that the steam is easily to enter, another encapsulation art is: introducing a Dam for block the organic layer to move left in order to solve the shadow effect of mask. Although the Dam can effectively solve the shadow effect of mask, but the Dam will make a frame of the device to be wider so that a narrow frame cannot be achieved. Besides, when adopting an ink-jet printing (IJP) method and a slot coating method to manufacture the organic layer, an ink overflow problem is generated, and the problem cannot be solved.

### SUMMARY OF THE INVENTION

The main technology problem solved by the present invention is to provide a thin-film packaging method for an OLED device and an OLED device, which can avoid a shadow effect of a mask, an overflow problem of ink at the edge, and can achieve a narrow frame requirement of the device.

In order to solve the above technology problem, a technology solution adopted by the present invention is: a thin-film packaging method for an OLED device, comprising: providing an OLED device to be packaged, and the OLED device to be packaged includes a light-emitting layer; through a lithography patterning technology to alternately form an inorganic thin film and an organic thin film on the OLED device in order to perform a thin-film packaging for the OLED device; wherein, the step of alternately forming an inorganic thin film and an organic thin film includes: forming a photoresist layer that surrounds the light-emitting layer of the OLED device on the OLED device to be packaged, and forming the inorganic thin film and the organic thin film on an opening region of the photoresist layer; wherein the one inorganic thin film and the organic thin film which are formed alternately includes a first inorganic thin film, a first organic thin film and a second inorganic thin film, wherein the second inorganic thin film completely covers the first organic thin film; wherein a material of the inorganic thin film is one of or a combination of Al2O3, TiO2, SiNx, SiCNx and SiOx.

In order to solve the above technology problem, another technology solution adopted by the present invention is: a thin-film packaging method for an OLED device, comprising: providing an OLED device to be packaged, and the OLED device to be packaged includes a light-emitting layer; through a lithography patterning technology to alternately form an inorganic thin film and an organic thin film on the OLED device in order to perform a thin-film packaging for the OLED device; wherein the step of forming the inorganic thin film and the organic thin film respectively includes a step of: forming a photoresist layer that surrounds the light-emitting layer of the OLED device to be packaged on the OLED device to be package, and forming the inorganic thin film/organic thin film at the opening region of the photoresist layer.

In order to solve the above technology problem, another technology solution adopted by the present invention is: an OLED device, comprising: an OLED device to be packaged, and the OLED device to be packaged includes a light-emitting layer; a first inorganic thin film formed on the OLED device to be packaged, and the first inorganic thin film surrounds and covers the light-emitting layer of the OLED device; a first organic thin film formed on the first inorganic thin film, and The first organic thin film 21 completely covers the light-emitting layer 30 of the OLED device; a second inorganic thin film formed on the first organic thin film, and first inorganic thin film and the second inorganic thin film surrounds the first organic thin film; wherein an included angle between a horizontal surface and each of a film wall of the first inorganic thin film, a film wall of the first organic thin film and a film wall of the second inorganic thin film is not equal to 90 degrees.

The beneficial effect of this application is: comparing to the conventional art, the OLED device to be packaged in the embodiment of the present invention: through a lithography patterning technology to alternately form an inorganic thin film and an organic thin film on the OLED device in order to perform a thin-film packaging for the OLED device. Wherein the step of forming the inorganic thin film and the organic thin film respectively includes a step of: forming a photoresist layer that surrounds the light-emitting layer of the OLED device to be packaged on the OLED device to be package, and forming the inorganic thin film/organic thin film at the opening region of the photoresist layer. Because of the lithography patterning technology, edge portion of the inorganic thin film and the organic thin film can be removed such that the shadow effect of a mask can be avoided; an overflow problem of ink at the edge can be solved, and can achieve a narrow frame requirement of the device.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a flow chart of a thin-film packaging method for an OLED device according to an embodiment of the present invention;

FIG. 2 is a flow chart of a thin-film packaging method for an OLED device according to another embodiment of the present invention;

FIG. 3 is a schematic application diagram of a thin-film packaging method for an OLED device according to an embodiment of the present invention;

FIG. 4 is a schematic application diagram of a thin-film packaging method for an OLED device according to another embodiment of the present invention;

FIG. 5 is a schematic application diagram of a thin-film packaging method for an OLED device according to another embodiment of the present invention;

FIG. 6 is a schematic application diagram of a thin-film packaging method for an OLED device according to another embodiment of the present invention;

FIG. 7 is a schematic application diagram of a thin-film packaging method for an OLED device according to another embodiment of the present invention;

FIG. 8 is a schematic application diagram of a thin-film packaging method for an OLED device according to another embodiment of the present invention; and

FIG. 9 is a schematic diagram of an OLED device according to an embodiment of the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

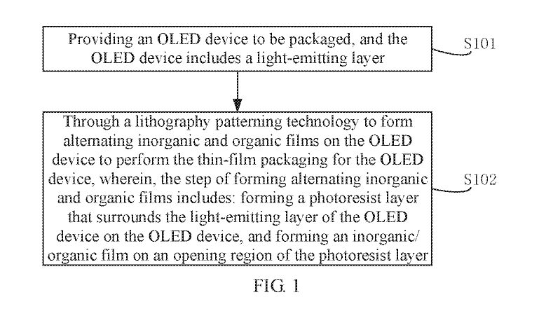

With reference to FIG. 1, FIG. 1 is a flow chart of a thin-film packaging method of an OLED device of the present invention. The method includes:

Step S101: providing an OLED device to be packaged, and the OLED device to be packaged includes a light-emitting layer.

Step S102: through a lithography patterning technology to form alternating inorganic and organic films on the OLED device in order to perform the thin-film packaging for the OLED device. Wherein, the step of forming alternating inorganic and organic films includes: forming a photoresist layer that surrounds the light-emitting layer of the OLED device on the OLED device to be packaged, and forming an inorganic/organic film on an opening region of the photoresist layer.

The lithography patterning technology means that under an illumination and through a photoresist, transferring a pattern on the mask to a substrate. The main process is: an UV light irradiates a surface of a substrate provided with a photoresist thin film through a mask so as to cause the photoresist at an exposure region to generate a chemical reaction;

In the conventional art, one encapsulation art is: an organic monomer forms a polymer having a certain chain length after a chemical reaction under the function of Plasma. Then the polymer is deposited in a substrate, that is, an organic layer. However, in the deposition process, some of the organic layer is shifted out off an organic packing region in order to form a shadow effect. When the organic layer is shifted to a film coating region of an inorganic layer, an adhesion force among layers will decrease such that the steam is easily to enter. Through the method of the present application, the shift portion at the edge of the organic layer and inorganic layer can be removed so that the shadow effect of the mask in the conventional art can be avoided.

In the conventional art, another encapsulation art is: introducing a Dam for block the organic layer to move left in order to solve the shadow effect of mask, but the Dam will make a frame of the device to be wider so that a narrow frame cannot be achieved. Besides, when adopting an ink-jet printing (IJP) method and a slot coating method to manufacture the organic layer, an ink overflow problem is generated at the edge, and the problem cannot be solved. Through the method of the present application, the shift portion at the edge of the organic layer and inorganic layer can be removed so that the shadow effect of the mask in the conventional art can be avoided. Without intruding the Dam, the narrow frame requirement can be achieved and eliminate the ink overflow problem at the edge.

The OLED device to be packaged in the embodiment of the present invention: through a lithography patterning technology to alternately form an inorganic thin film and an organic thin film on the OLED device in order to perform a thin-film packaging for the OLED device. Wherein the step of forming the inorganic thin film and the organic thin film respectively includes a step of: forming a photoresist layer that surrounds the light-emitting layer of the OLED device to be packaged on the OLED device to be package, and forming the inorganic thin film/organic thin film at the opening region of the photoresist layer. Because of the lithography patterning technology, edge portion of the inorganic thin film and the organic thin film can be removed such that the shadow effect of a mask can be avoided; an overflow problem of ink at the edge can be solved, and can achieve a narrow frame requirement of the device. Specifically, the frame edge of the device can be reduced to less than 1 mm.

Wherein the inorganic thin film is formed by a Plasma Enhanced Chemical Vapor Deposition (PECVD), an Atomic layer deposition (ALD), a Pulsed Laser Deposition (PLD) or a Sputter Deposition.

In another embodiment, the organic thin film can be formed through an Ink Jet Printing (IJP) or a slot coating.

Wherein, a material of the inorganic thin film is one of or a combination of Al2O3, TiO2, SiNx, SiCNx and SiOx for increasing the water blocking function. The organic thin film can include but not limited to Acryl, Hexamethyldisiloxane (HMDSO), Polyacrylates, Polycarbonates, Polystyrene for buffering the stress in bending and folding and covering the particle pollutants.

In one embodiment, a thickness of the inorganic thin film is less than 1 μm, and a thickness of the organic thin film is less than 15 μm.

The inorganic thin film and the organic thin film are formed alternatively, or formed by another ways, not limited here. The inorganic thin film and the organic thin film can be multiple layers.

In one embodiment, the OLED device to be packaged includes a light-emitting layer and a flexible substrate which are stacked. Specifically, the step of forming the inorganic thin film includes steps of:

Coating a photoresist layer on the OLED device to be packaged, through exposing and developing to form the opening region at the photoresist layer such that the light-emitting layer of the OLED device to be packaged is revealed at the opening region, and the photoresist layer outside the opening region surrounds the light-emitting of the OLED device to be packaged, forming an inorganic thin film at the opening region of the photoresist layer, and the inorganic thin film completely covers the flexible substrate of the OLED device to be packaged.

In the present embodiment, if the material of the photoresist layer is a positive photoresist, an exposure region of the mask should align to the opening region of the photoresist layer, if the material of the photoresist layer is a negative photoresist, a non-exposure region of the mask should align to the opening region of the photoresist layer. Accordingly, after exposing through the mask, and after developing, the photoresist layer can form the opening region.

Specifically, on the base of the above embodiment, the step of forming the organic thin film includes: forming a photoresist layer that surrounds the inorganic thin film on the inorganic thin film, through exposing and developing to form an opening region of the photoresist layer located on the inorganic thin film, wherein a width of the opening region is less than a width of the inorganic thin film such that the photoresist layer outside the opening region surrounds the inorganic thin film, the opening region of the photoresist layer located on the inorganic thin film forms an organic thin film, and the organic thin film completely covers the light-emitting layer of the OLED device to be packaged.

Similarly, if the material of the photoresist layer is a positive photoresist, an exposure region of the mask should align to the opening region of the photoresist layer, if the material of the photoresist layer is a negative photoresist, a non-exposure region of the mask should align to the opening region of the photoresist layer. Accordingly, after exposing through the mask, and after developing, the photoresist layer can form the opening region.

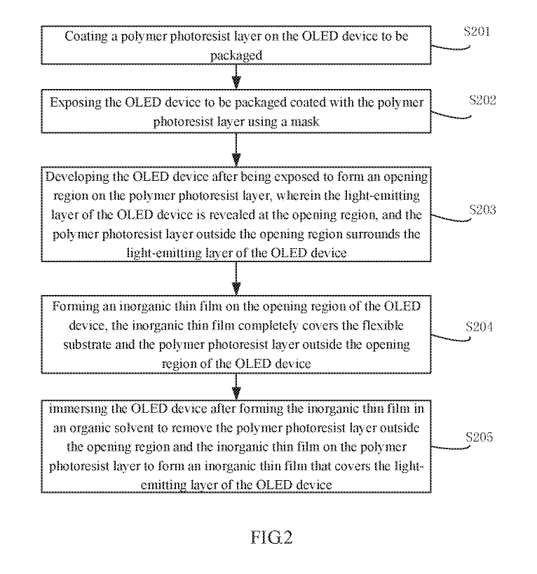

With reference to FIG. 2 also, in one embodiment, forming a layer of inorganic thin film on the OLED device to be packaged. Then, forming a layer of organic thin film on the inorganic thin film. Wherein, the method for forming the inorganic thin film can includes:

Step S201: coating a polymer photoresist layer on the OLED device to be packaged.

Step S202: exposing the OLED device to be packaged coated with the polymer photoresist layer using a mask.

Step S203: developing the OLED device to be packaged after being exposed in order to form an opening region on the polymer photoresist layer, wherein the light-emitting layer of the OLED device to be packaged is revealed at the opening region, and the polymer photoresist layer outside the opening region surrounds the light-emitting layer of the OLED device to be packaged.

Step S204: forming an inorganic thin film on the opening region of the OLED device to be packaged, wherein the inorganic thin film completely covers the flexible substrate and the polymer photoresist layer outside the opening region of the OLED device to be packaged.

Step S205: immersing the OLED device to be packaged after forming the inorganic thin film in an organic solvent in order to remove the polymer photoresist layer outside the opening region and the inorganic thin film on the polymer photoresist layer so as to form an inorganic thin film that covers the light-emitting layer of the OLED device to be packaged.

In the present embodiment, a material of the polymer photoresist layer can be polymer positive photoresist or polymer negative photoresist. If the material of the polymer photoresist layer is a polymer positive photoresist, an exposure region of the mask should align to the opening region of the polymer photoresist layer, if the material of the polymer photoresist layer is a polymer negative photoresist, a non-exposure region of the mask should align to the opening region of the polymer photoresist layer. Accordingly, after exposing through the mask, and after developing, the photoresist layer can form the opening region.

Forming an inorganic thin film on the OLED device to be packaged, then, forming an organic layer on the inorganic thin film, and using polymer photoresist as a polymer negative photoresist for example, the above process includes:

A: covering a fluorine-containing polymer negative photoresist on the OLED device to be packaged, wherein a non-exposure region of the mask covers the light-emitting layer of the OLED device.

B: exposing the OLED device to be packaged covering with the fluorine-containing polymer negative photoresist in order to remove the polymer negative photoresist.

C: developing the OLED device to be packaged after being exposed in order to remove the polymer negative photoresist without being exposed.

D: depositing an inorganic thin film on the OLED device after removing the polymer negative photoresist not being exposed such that the inorganic thin film completely covers the flexible substrate of the OLED device.

E: immersing the OLED device to be packaged after forming the inorganic thin film in an organic solvent in order to remove the polymer negative photoresist layer and the inorganic thin film on the polymer negative photoresist layer so as to form an inorganic thin film that covers the light-emitting layer of the OLED device to be packaged.

F: using a lithography patterning technology to deposit an organic thin film on the inorganic thin film, wherein the organic thin film completely covers the light-emitting layer of the OLED device to be packaged.

It should be noted that the light-emitting layer of the OLED device to be packaged is a light-emitting region of the OLED device to be packaged, and is a necessary organic multi-layered sub-device of a plane region. The flexible substrate of the OLED device to be packaged is a flexible base under the light-emitting layer of the OLED device to be packaged. Besides, the method of the present application is also suitable for a non-flexible substrate in the OLED device such as a glass substrate.

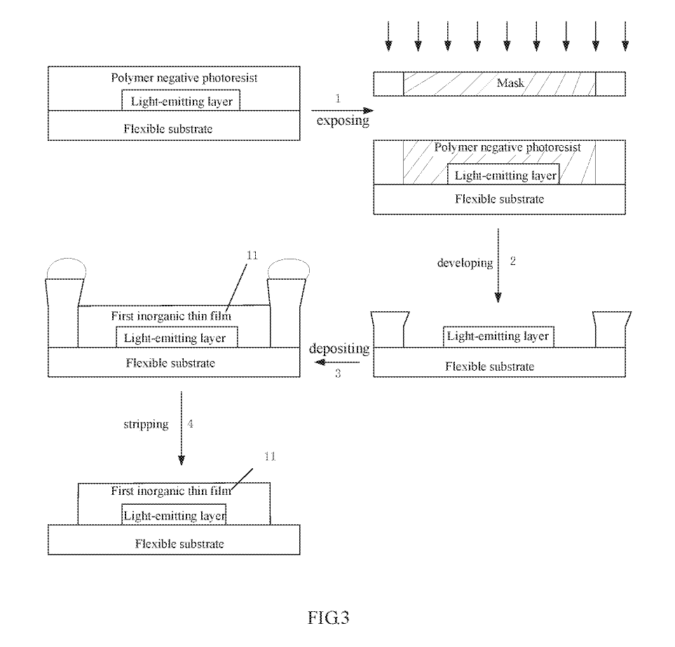

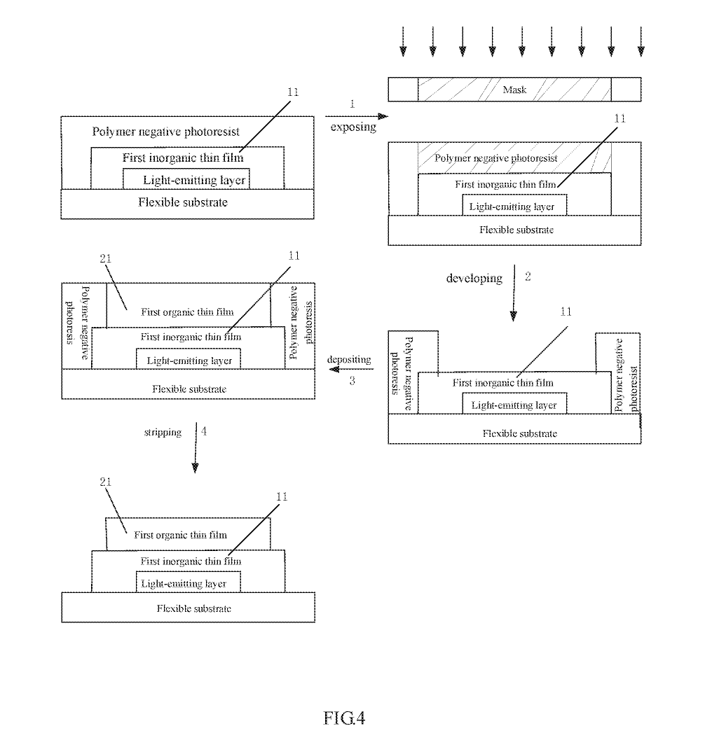

Superficially, with reference to FIG. 3 and FIG. 4, in a spherically application, using a coating machine (spin-coater) to coat a fluorine-containing polymer negative photoresist on the OLED device, covering an entire surface of the device. The thickness is Several to several tens of microns, drying at 80° C. for 10 min; then exposing. Using a non-exposure region of the mask to cover the light-emitting layer of the OLED device to ensure that the light-emitting layer of the OLED device is completely located at a non-exposure region. The development is then performed to remove the negative photoresist (shadow portion) of the unexposed portion of the polymer. In one embodiment, the remaining unexposed polymer negative photoresist is completely removed and O2 plasma etching is used (O2 Plasma etching) for 1 min.

As shown in a process 3 in FIG. 3, a first inorganic thin film 11 is deposited on the substrate by PECVD, ALD, PLD, or Sputter, and a thickness is 0.5-1 μm. The thin film is required to completely cover the flexible substrate of the OLED to be packaged. The material of the inorganic thin film includes, but is not limited to, one or a combination of two or more of Al2O₃, TiO₂, SiNx, SiCNx, SiOx, and the like, an inorganic functional material for increasing the water blocking function.

As shown in the process 4 in FIG. 3, the OLED device to be packaged is soaked in an organic solvent for a soaking time of 1 to 30 minutes, the exposed polymer negative photoresist is removed, and the inorganic thin film deposited on the negative photoresist of the polymer is removed to leave other materials on the substrate.

With reference to FIG. 4, using IJP or slot coating and the lithography patterning technology in FIG. 3 to manufacture a first organic thin film 21 having a thickness of 4-8 μm, and requires that the organic thin film completely cover the light-emitting layer of the OLED to be packaged. The material of the organic thin film is not limited to Acryl, HMDSO, polyacrylates, polycarbonates, polystyrene, and the like used for buffering the stress when bent, folded, and the coverage of particle contaminants.

In one embodiment, the inorganic thin film and the organic thin film which are formed alternately includes a first inorganic thin film, a first organic thin film and a second inorganic thin film, wherein the second inorganic thin film completely covers the first organic thin film.

Specifically, using PECVD, ALD, PLD or Sputter and inorganic material of the lithography patterning technology to deposit a second inorganic thin film 12 on the first organic thin film 21, and the second thin inorganic film 12 completely covers the first organic film 21. The material of the inorganic film includes, but is not limited to, one or a combination of two or more of Al₂O₃, TiO₂, SiNx, SiCNx, SiOx, etc., for blocking the external water vapor from etching the OLED device, as shown in FIG. 5.

In one embodiment, in step S102, the alternating inorganic thin film and the organic thin film respectively include: a first inorganic thin film, a first organic thin film, a second inorganic thin film, and a second organic thin film and a third inorganic thin film that are sequentially formed on the OLED device to be packaged. Wherein the second inorganic thin film completely covers the first organic thin film, and the third inorganic thin film completely covers the second organic thin film, and the inorganic thin films have the same material, thickness and preparation method. The organic thin films have the same thickness and preparation method.

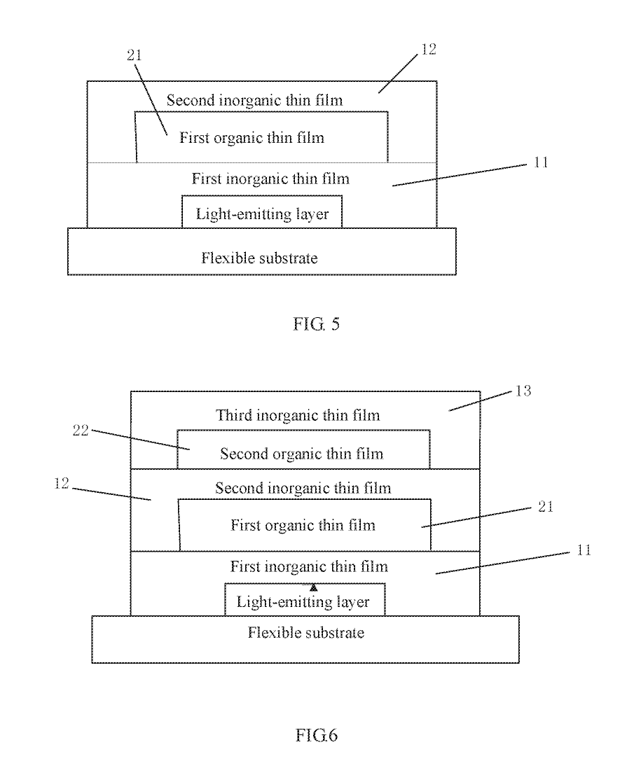

Specifically, in this embodiment, the structural units of the inorganic thin film and the organic thin film are repeated, and the second inorganic thin film 12 is prepared on the second organic thin film 22 by IJP or slot coating, and using the PECVD, ALD, PLD, or Sputter to deposit a third inorganic thin film 13 in the second organic thin film 22. The inorganic thin films have the same material, thickness and preparation method. The organic thin films have the same thickness and preparation method, as shown in FIG. 6.

Furthermore, in one embodiment, a covering region of the second organic thin film is greater than a covering region of the first organic thin film.

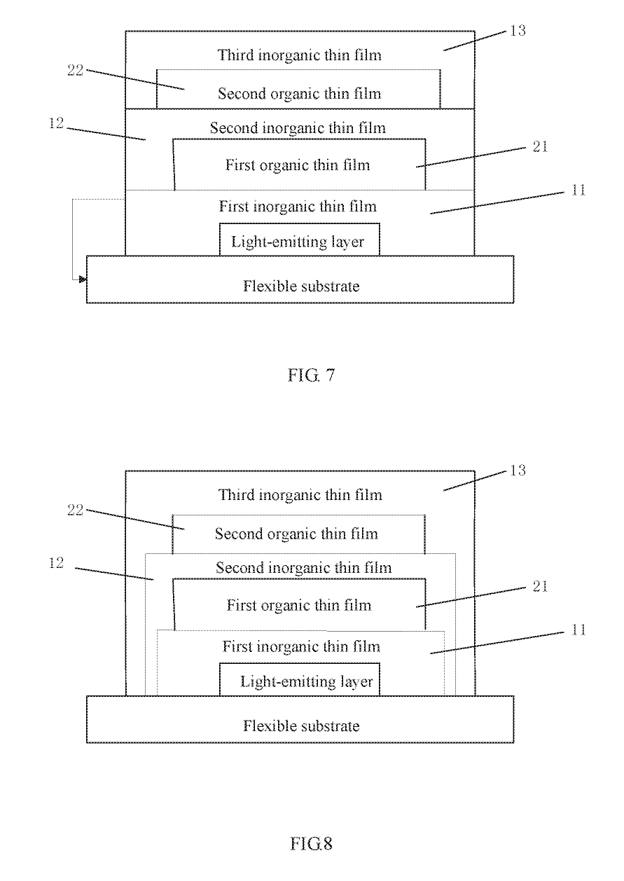

Specifically, in this embodiment, the structural units of the inorganic thin film and the organic thin film are repeated, with the photolithography patterning technology, the second inorganic thin film 12 is prepared on the second organic thin film 22 by IJP or slot coating, and using the PECVD, ALD, PLD, or Sputter to deposit a third inorganic thin film 13 in the second organic thin film 22. The inorganic thin films have the same material, thickness and preparation method. The organic thin films have the same thickness and preparation method, as shown in FIG. 7.

Furthermore, in one embodiment, a covering region of the third inorganic thin film is greater than a covering region of the second inorganic thin film. Furthermore, a covering region of the second inorganic thin film is greater than a covering region of the first inorganic thin film.

Specifically, in this embodiment, the structural units of the inorganic thin film and the organic thin film are repeated, with the photolithography patterning technology, the second organic thin film 22 is prepared on the second organic thin film 12 by IJP or slot coating, and the covering region of the second organic thin film 22 is greater than a covering region of the first organic thin film, and using the PECVD, ALD, PLD, or Sputter to deposit a third inorganic thin film 13 on the second organic thin film 22, a covering region of the third inorganic thin film 13 is greater than a covering region of the second inorganic thin film 12, a covering region of the second inorganic thin film 12 is greater than a covering region of the first inorganic thin film 11. The inorganic thin films have the same material, thickness and preparation method. The organic thin films have the same thickness and preparation method, as shown in FIG. 8.

The basic structure of the OLED device includes, in addition to the above-mentioned light-emitting layer, flexible substrate, alternating inorganic thin film and organic thin film, other sub-devices such as an anode, a cathode, and the like. Therefore, in the above content and the corresponding schematic diagram, in the actual packaging process of the OLED device, in addition to encapsulating the above-mentioned light-emitting layer, the flexible substrate, the alternating inorganic thin film and organic thin film, other sub-devices are included (not shown in the figure), but not limited here.

Through the above way, because of the lithography patterning technology, when manufacturing the inorganic/organic thin film, edge portion of the inorganic thin film and the organic thin film can be removed such that the shadow effect of a mask can be avoided, an overflow problem of ink at the edge can be solved, and can achieve a narrow frame requirement of the device. Specifically, the frame edge of the device can be reduced to less than 1 mm.

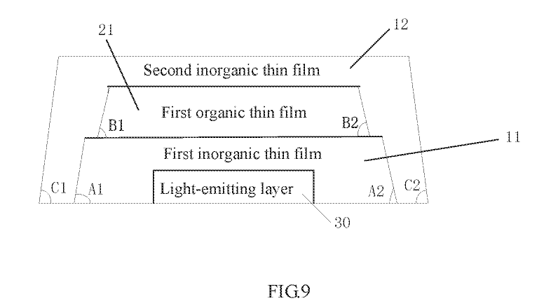

With reference to FIG. 9, FIG. 9 is a schematic diagram of an OLED device according to an embodiment of the present invention. The OLED device includes: an OLED device to be packaged, wherein the OLED device to be packaged includes a light-emitting layer 30, a first inorganic thin film 11, a first organic thin film 21 and a second inorganic thin film 12.

Wherein the first inorganic thin film 11 is formed on the OLED device 30 to be packaged, and surrounds and covers the light-emitting layer 30 of the OLED device. The first organic thin film 21 is formed on the first inorganic thin film 11. The first organic thin film 21 completely covers the light-emitting layer 30 of the OLED device. The second inorganic thin film 12 is formed on the first organic thin film 21, and the first inorganic thin film 11 and a second inorganic thin film 13 packages the first organic thin film 21.

Wherein an included angle between a horizontal surface and each of a film wall of the first inorganic thin film 11, a film wall of the first organic thin film 21 and a film wall of the second inorganic thin film 12 is not equal to 90 degrees. As shown in FIG. 9, an included angle A1 and A2 between a horizontal surface and a film wall of the first inorganic thin film 11 is not equal to 90 degrees, an included angle B1 and B2 between a horizontal surface and a film wall of the first organic thin film 21 is not equal to 90 degrees, and an included angle C1 and C2 between a horizontal surface and a film wall of the second inorganic thin film 12 is not equal to 90 degrees.

It should be noted that an included angle between a horizontal surface and each of a film wall of the first inorganic thin film 11, a film wall of the first organic thin film 21 and a film wall of the second inorganic thin film 12 is not equal to 90 degrees is generated by the packaging process of the OLED device.

Furthermore, an included angle between a horizontal surface and each of a film wall of the first inorganic thin film 11, a film wall of the first organic thin film 21 and a film wall of the second inorganic thin film 12 is greater than or equal to 50 degrees.

The OLED device of the present embodiment includes: a light-emitting layer 30 of the OLED device to be packaged, a first inorganic thin film 1, a first organic thin film 21 and a second inorganic thin film 12. Wherein, the first inorganic thin film is formed on the OLED device to be packaged, and the first inorganic thin film 11 surrounds and covers the light-emitting layer 30 of the OLED device; the first organic thin film 21 is formed on the first inorganic thin film 11, and the first organic thin film 21 completely covers the light-emitting layer 30 of the OLED device; a second inorganic thin film 12 formed on the first organic thin film 21, and first inorganic thin film 11 and the second inorganic thin film 13 surrounds the first organic thin film 21. Because of the lithography patterning technology, edge portion of the inorganic thin film and the organic thin film can be removed such that the shadow effect of a mask can be avoided; an overflow problem of ink at the edge can be solved, and can achieve a narrow frame requirement of the device. Specifically, the frame edge of the device can be reduced to less than 1 mm.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A thin-film packaging method for an OLED device, comprising:
providing an OLED device to be packaged, and the OLED device to be packaged includes a light-emitting layer;
through a lithography patterning technology to alternately form an inorganic thin film and an organic thin film on the OLED device in order to perform a thin-film packaging for the OLED device;
wherein, the step of alternately forming an inorganic thin film and an organic thin film includes: forming a photoresist layer that surrounds the light-emitting layer of the OLED device on the OLED device to be packaged, and forming the inorganic thin film and the organic thin film on an opening region of the photoresist layer;
wherein the one inorganic thin film and the organic thin film which are formed alternately includes a first inorganic thin film, a first organic thin film and a second inorganic thin film, wherein the second inorganic thin film completely covers the first organic thin film;
wherein a material of the inorganic thin film is one of or a combination of Al₂O₃, TiO₂, SiNx, SiCNx and SiOx.

2. The thin-film packaging method for an OLED device according to claim 1, wherein the OLED device to be packaged includes a light-emitting layer and a flexible substrate which are stacked, and the step of forming the inorganic thin film includes steps of:
coating a photoresist layer on the OLED device to be packaged, through exposing and developing to form the opening region at the photoresist layer such that the light-emitting layer of the OLED device to be packaged is revealed at the opening region, and the photoresist layer outside the opening region surrounds the light-emitting of the OLED device to be packaged, forming an inorganic thin film at the opening region of the photoresist layer, and the inorganic thin film completely covers the flexible substrate of the OLED device to be packaged.

3. The thin-film packaging method for an OLED device according to claim 2, wherein the step of forming the organic thin film includes a step of: forming a photoresist layer that surrounds the inorganic thin film on the inorganic thin film, through exposing and developing to form an opening region of the photoresist layer located on the inorganic thin film, wherein a width of the opening region is less than a width of the inorganic thin film such that the photoresist layer outside the opening region surrounds the inorganic thin film, the opening region of the photoresist layer located on the inorganic thin film forms an organic thin film, and the organic thin film completely covers the light-emitting layer of the OLED device to be packaged.

4. The thin-film packaging method for an OLED device according to claim 2, wherein the step of forming the one organic thin film includes steps of:
coating a polymer photoresist layer on the OLED device to be packaged;
exposing the OLED device to be packaged coated with the polymer photoresist layer using a mask;
developing the OLED device to be packaged after being exposed in order to form an opening region on the polymer photoresist layer, wherein the light-emitting layer of the OLED device to be packaged is revealed at the opening region, and the polymer photoresist layer outside the opening region surrounds the light-emitting layer of the OLED device to be packaged;
forming an inorganic thin film on the opening region of the OLED device to be packaged, wherein the inorganic thin film completely covers the flexible substrate and the polymer photoresist layer outside the opening region of the OLED device to be packaged; and
immersing the OLED device to be packaged after forming the inorganic thin film in an organic solvent in order to remove the polymer photoresist layer outside the opening region and the inorganic thin film on the polymer photoresist layer so as to form an inorganic thin film that covers the light-emitting layer of the OLED device to be packaged.

5. The thin-film packaging method for an OLED device according to claim 1, wherein the inorganic thin film is formed by a Plasma Enhanced Chemical Vapor Deposition (PECVD), an atomic layer deposition (ALD), a Pulsed Laser Deposition (PLD) or a Sputter Deposition.

6. The thin-film packaging method for an OLED device according to claim 1, wherein a thickness of the inorganic thin film is less than 1 μm, and a thickness of the organic thin film is less than 15 μm.

7. A thin-film packaging method for an OLED device, comprising:
providing an OLED device to be packaged, and the OLED device to be packaged includes a light-emitting layer;
through a lithography patterning technology to alternately form an inorganic thin film and an organic thin film on the OLED device in order to perform a thin-film packaging for the OLED device;
wherein the step of forming the inorganic thin film and the organic thin film respectively includes a step of: forming a photoresist layer that surrounds the light-emitting layer of the OLED device to be packaged on the OLED device to be package, and forming the inorganic thin film/organic thin film at the opening region of the photoresist layer.

8. The thin-film packaging method for an OLED device according to claim 7, wherein the OLED device to be packaged includes a light-emitting layer and a flexible substrate which are stacked, and the step of forming the inorganic thin film includes steps of:
coating a photoresist layer on the OLED device to be packaged, through exposing and developing to form the opening region at the photoresist layer such that the light-emitting layer of the OLED device to be packaged is revealed at the opening region, and the photoresist layer outside the opening region surrounds the light-emitting of the OLED device to be packaged, forming an inorganic thin film at the opening region of the photoresist layer, and the inorganic thin film completely covers the flexible substrate of the OLED device to be packaged.

9. The thin-film packaging method for an OLED device according to claim 8, wherein the step of forming the organic thin film includes a step of: forming a photoresist layer that surrounds the inorganic thin film on the inorganic thin film, through exposing and developing to form an opening region of the photoresist layer located on the inorganic thin film, wherein a width of the opening region is less than a width of the inorganic thin film such that the photoresist layer outside the opening region surrounds the inorganic thin film, the opening region of the photoresist layer located on the inorganic thin film forms an organic thin film, and the organic thin film completely covers the light-emitting layer of the OLED device to be packaged.

10. The thin-film packaging method for an OLED device according to claim 8, wherein the step of forming the one organic thin film includes steps of:
coating a polymer photoresist layer on the OLED device to be packaged;
exposing the OLED device to be packaged coated with the polymer photoresist layer using a mask;
developing the OLED device to be packaged after being exposed in order to form an opening region on the polymer photoresist layer, wherein the light-emitting layer of the OLED device to be packaged is revealed at the opening region, and the polymer photoresist layer outside the opening region surrounds the light-emitting layer of the OLED device to be packaged;
forming an inorganic thin film on the opening region of the OLED device to be packaged, wherein the inorganic thin film completely covers the flexible substrate and the polymer photoresist layer outside the opening region of the OLED device to be packaged; and
immersing the OLED device to be packaged after forming the inorganic thin film in an organic solvent in order to remove the polymer photoresist layer outside the opening region and the inorganic thin film on the polymer photoresist layer so as to form an inorganic thin film that covers the light-emitting layer of the OLED device to be packaged.

11. The thin-film packaging method for an OLED device according to claim 7, wherein the inorganic thin film and the organic thin film which are formed alternately includes a first inorganic thin film, a first organic thin film and a second inorganic thin film, wherein the second inorganic thin film completely covers the first organic thin film.

12. The thin-film packaging method for an OLED device according to claim 7, the inorganic thin film is formed by a Plasma Enhanced Chemical Vapor Deposition (PECVD), an atomic layer deposition (ALD), a Pulsed Laser Deposition (PLD) or a Sputter Deposition.

13. The thin-film packaging method for an OLED device according to claim 7, wherein a material of the inorganic thin film is one of or a combination of Al₂O₃, TiO₂, SiNx, SiCNx and SiOx, and a thickness of the inorganic thin film is less than 1 μm, and a thickness of the organic thin film is less than 15 μm.

14. An OLED device, comprising:
an OLED device to be packaged, and the OLED device to be packaged includes a light-emitting layer;
a first inorganic thin film formed on the OLED device to be packaged, and the first inorganic thin film surrounds and covers the light-emitting layer of the OLED device;
a first organic thin film formed on the first inorganic thin film, and The first organic thin film completely covers the light-emitting layer of the OLED device;
a second inorganic thin film formed on the first organic thin film, and first inorganic thin film and the second inorganic thin film surrounds the first organic thin film;
wherein an included angle between a horizontal surface and each of a film wall of the first inorganic thin film, a film wall of the first organic thin film and a film wall of the second inorganic thin film is not equal to 90 degrees.

15. The OLED device according to claim 14, wherein the included angle is greater than or equal to 50 degrees.
